(19) United States
(12) Patent Application Publication
(10) Pub. No.: US 2025/0357723 A1
(43) Pub. Date: Nov. 20, 2025

(54) SEMICONDUCTOR OPTICAL INTEGRATED ELEMENT AND MANUFACTURING METHOD

(71) Applicant: Mitsubishi Electric Corporation, Tokyo (JP)

(72) Inventors: Yosuke SUZUKI, Chiyoda-ku, Tokyo (JP); Satoshi NISHIKAWA, Chiyoda-ku, Tokyo (JP)

(73) Assignee: Mitsubishi Electric Corporation, Tokyo (JP)

(21) Appl. No.: 18/867,013

(22) PCT Filed: May 26, 2022
(86) PCT No.: PCT/JP2022/021520

§ 371 Date: Nov. 19, 2024

(51) Int. Cl. H01S 5/026; H01S 5/343

(52) U.S. Cl. CPC H01S 5/0265; H01S 5/343

(57) ABSTRACT

A semiconductor optical integrated element includes a laser active layer, an optical modulation active layer, an optical amplification active layer, a first upper clad layer, and a second upper clad layer. The optical modulation active layer is juxtaposed to the laser active layer. The optical amplification active layer is juxtaposed to the optical modulation active layer. The first upper clad layer has a first index of refraction and is arranged on an upper surface of the laser active layer and an upper surface of the optical modulation active layer. The second upper clad layer has a second index of refraction different, and is juxtaposed to the first upper clad layer and arranged on an upper surface of the optical amplification active layer. Amplified laser beams outputted from the optical amplification active layer are outputted as being shifted above modulated laser beams outputted from the optical modulation active layer.

### TECHNICAL FIELD

The present invention relates to a semiconductor optical integrated element and a method of manufacturing the same, and specifically relates to a semiconductor optical integrated element to generate laser beams with a semiconductor and to output laser beams and a method of manufacturing the same.

### BACKGROUND ART

A semiconductor optical integrated element to generate laser beams with a semiconductor and to output laser beams has been known as one of devices for optical communication. For example, a semiconductor optical integrated element in which a laser portion, an electro absorption (EA) optical modulator, and a semiconductor optical amplifier (SOA) are integrated has been known (for example, PTL 1 and PTL 2).

In such a conventional semiconductor optical integrated element, the laser portion generates laser beams in accordance with an injected current. The EA modulator performs a function for modulation with an effect of variation in light absorption spectrum of a semiconductor layer in accordance with an applied voltage, and generates modulated laser beams obtained by modulation of laser beams generated by the laser portion. The semiconductor optical amplifier performs a function to increase light intensity by stimulated emission in accordance with the injected current, and generates amplified laser beams obtained by amplification of modulated laser beams modulated by the EA modulator.

In such a conventional semiconductor optical integrated element, for example, the laser portion has a structure in which a lower separate confinement heterostructure (SCH) layer, a multiple quantum well layer (MQW), an tipper SCH layer, a diffraction grating layer, and a semiconductor layer serving as an upper clad layer are sequentially formed on an InP substrate also serving as a lower clad layer. In such a conventional semiconductor optical integrated element, for example, an SOA portion has a structure in which the lower SCH layer, the multiple quantum well layer, the upper SCH layer, and the semiconductor layer serving as the upper clad layer are sequentially formed on the InP substrate also serving as the lower clad layer.

### CITATION LIST

### Patent Literature

PTL 1: Japanese Patent Laying-Open No. 6-53596
PTL 2: WO2021/059447

### SUMMARY OF INVENTION

### Technical Problem

With spread of an optical communication technique, however, further increase in output from the semiconductor optical integrated element has been expected.

The present invention was made in view of circumstances above, and an object thereof is to provide a semiconductor optical integrated element that can achieve further increase in output.

### Solution to Problem

A semiconductor optical integrated element according to one aspect of the present invention generates and outputs laser beams, and includes a laser active layer, an optical modulation active layer, an optical amplification active layer, a first upper clad layer, and a second upper clad layer. The laser active layer generates laser beams. The optical modulation active layer is juxtaposed to the laser active layer and outputs modulated laser beams obtained by optical modulation of laser beams generated by the laser active layer. The optical amplification active layer is juxtaposed to the optical modulation active layer and outputs amplified laser beams obtained by amplification of intensity of the modulated laser beams outputted from the optical modulation active layer. The first upper clad layer has a first index of refraction and is arranged on an upper surface of the laser active layer and an upper surface of the optical modulation active layer. The second upper clad layer has a second index of refraction different from the first index of refraction, and is juxtaposed to the first upper clad layer and arranged on an upper surface of the optical amplification active layer. The amplified laser beams outputted from the optical amplification active layer are outputted as being shifted above the modulated laser beams outputted from the optical modulation active layer.

A manufacturing method of manufacturing a semiconductor optical integrated element to generate and output laser beams according to one aspect of the present invention includes a laser active layer arrangement step, an optical modulation active layer arrangement step, an optical amplification active layer arrangement step, a first upper clad layer arrangement step, a material selection step, and a second upper clad layer arrangement step. In the laser active layer arrangement step, a laser active layer to generate laser beams is arranged. In the optical modulation active layer arrangement step, an optical modulation active layer to output modulated laser beams obtained by optical modulation of laser beams generated by the laser active layer arranged in the laser active layer arrangement step is arranged as being juxtaposed to the laser active layer. In the optical amplification active layer arrangement step, an optical amplification active layer to output amplified laser beams obtained by amplification of intensity of modulated laser beams outputted from the optical modulation active layer arranged in the optical modulation active layer arrangement step is arranged as being juxtaposed to the optical modulation active layer. In the first upper clad layer arrangement step, a first upper clad layer having a first index of refraction is arranged on an upper surface of the laser active layer arranged in the laser active layer arrangement step and an upper surface of the optical modulation active layer arranged in the optical modulation active layer arrangement step. In the material selection step, a material having a second index of refraction different from the first index of refraction is selected. In the second upper clad layer arrangement step, a second upper clad layer having the second index of refraction by containing a material selected in the material selection step is arranged on an upper surface of the optical amplification active layer arranged in the optical amplification active layer arrangement step.

### Advantageous Effects of Invention

According to one aspect of the present invention, a semiconductor optical integrated element that can achieve further increase in output can be provided.

### BRIEF DESCRIPTION OF DRAWINGS

FIG. 1 is a cross-sectional view schematically showing a semiconductor optical integrated element according to a first embodiment.

### DESCRIPTION OF EMBODIMENTS

An embodiment of a semiconductor optical integrated element disclosed in the present application will be described below in detail with reference to the drawings. Specifically, the semiconductor optical integrated element to generate and output laser beams will be described. Embodiments shown below are by way of example and these embodiments do not limit the present invention.

### First Embodiment

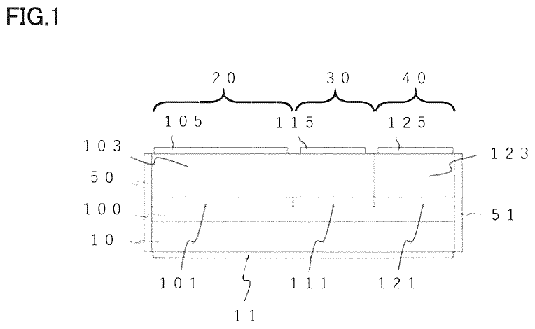

FIG. 1 is a cross-sectional view schematically showing a semiconductor optical integrated element 1 according to a first embodiment. Semiconductor optical integrated element 1 is a device to generate and output laser beams. As shown in FIG. 1, semiconductor optical integrated element 1 includes a lower electrode 11, a semiconductor substrate 10, a lower clad layer 100, a laser active layer 101, an optical modulation active layer 111, an optical amplification active layer 121, a first upper clad layer 103, a second upper clad layer 123, a laser active electrode 105, an optical modulation electrode 115, an optical amplification electrode 125, and the like.

Lower electrode 11 is a plate-like electrode for providing a current between lower electrode 11, and laser active electrode 105, optical modulation electrode 115, and optical amplification electrode 125 which will be described later. Lower electrode 11 is arranged such that laser active layer 101, optical modulation active layer 111, and optical amplification active layer 121 which will be described later are located between lower electrode 11, and laser active electrode 105, optical modulation electrode 115, and optical amplification electrode 125.

Semiconductor substrate 10 is a plate-like portion that functions as a substrate for arrangement of each element. Semiconductor substrate 10 is arranged on an upper surface of lower electrode 11. Semiconductor substrate 10 is composed, for example, of indium phosphide (InP).

Lower clad layer 100 is a semiconductor layer to give activity to laser active layer 101, optical modulation active layer 111, and optical amplification active layer 121. Lower clad layer 100 is arranged on an upper surface of semiconductor substrate 10. Lower clad layer 100 is arranged such that lower clad layer 100, together with first upper clad layer 103 and second upper clad layer 123 which will be described later, sandwiches laser active layer 101, optical modulation active layer 111, and optical amplification active layer 121 therebetween. Lower clad layer 100 has a lower clad layer index of refraction which is a prescribed index of refraction, and it is composed, for example, of InP.

Laser active layer 101 is a plate-like portion to oscillate laser at a prescribed wavelength to generate laser beams by injection of a current supplied from lower electrode 11 and laser active electrode 105. Laser active layer 101 is arranged between lower electrode 11 and laser active electrode 105. Laser active layer 101 outputs generated laser beams to optical modulation active layer 111 which will be described later. Laser active layer 101 is arranged on apart of an upper surface of lower clad layer 100. Laser active layer 101 has a laser active layer index of refraction which is a prescribed index of refraction, is a semiconductor layer composed, for example, of AlGaInAs or InGaAsP of a quantum well structure (MQW), and is composed of a structure in which layers different in ratio of materials are layered.

Optical modulation active layer 111 is a plate-like portion to modulate light by varying a light absorptance of laser beams generated and outputted by laser active layer 101 with a voltage applied by lower electrode 11 and optical modulation electrode 115 for carrying signal information on intensity of light as adopted in intensity modulation-direct detection (IM-DD) in an optical communication system. Optical modulation active layer 111 is arranged between lower electrode 11 and optical modulation electrode 115. Optical modulation active layer 111 outputs modulated laser beams which are modulated laser beams to optical amplification active layer 121 which will be described later. Optical modulation active layer 1l1 has an optical modulation active layer index of refraction which is a prescribed index of refraction, is a semiconductor layer composed, for example, of AlGaInAs or InGaAsP of the quantum well structure, and is composed of a structure in which layers different in ratio of materials are layered.

Optical amplification active layer 121 is a plate-like portion to amplify intensity of modulated laser beams outputted as a result of optical modulation by optical modulation active layer 111, by injection of a current supplied from lower electrode 11 and optical amplification electrode 125 for compensation for loss in optical signal transmission in the optical communication system. Optical amplification active layer 121 is arranged between lower electrode 11 and optical amplification electrode 125. Optical amplification active layer 121 outputs to the outside, amplified laser beams which are modulated laser beams amplified in intensity. Optical amplification active layer 121 has an optical amplification active layer index of refraction which is a prescribed index of refraction, is a semiconductor layer composed, for example, of AlGaInAs or InGaAsP of the quantum well structure, and is composed of a structure in which layers different in ratio of materials are layered.

First upper clad layer 103 is a semiconductor layer arranged at a position where first upper clad layer 103, together with lower clad layer 100, sandwiches laser active layer 101 and optical modulation active layer 111 therebetween. As shown in FIG. 1, first upper clad layer 103 is arranged to cover laser active layer 101 and optical modulation active layer 111. First upper clad layer 103 performs a function to give laser activity to laser active layer 101 and to give optical modulation activity to optical modulation active layer 111 by being arranged together with lower clad layer 100. First upper clad layer 103 has a first index of refraction which is a prescribed index of refraction and is composed, for example, of InP.

Second upper clad layer 123 is a semiconductor layer arranged at a position where second upper clad layer 123, together with lower clad layer 100, sandwiches optical amplification active layer 121 therebetween. As shown in FIG. 1, second upper clad layer 123 is arranged adjacently to first upper clad layer 103 not to cover laser active layer 101 and optical modulation active layer 111 but to cover optical amplification active layer 121. Second upper clad layer 123 performs a function to give optical amplification activity to optical amplification active layer 121 and to give optical amplification activity to optical amplification active layer 121, by being arranged together with lower clad layer 100. Second upper clad layer 123 has a second index of refraction which is a prescribed index of refraction and is composed, for example, of InGaAsP or AlGaInAs.

The lower clad layer index of refraction of lower clad layer 100 and the first index of refraction of first upper clad layer 103 are both configured to be lower than the laser active layer index of refraction which is the index of refraction of laser active layer 101. According to such a configuration, diffusion of laser beams outputted from laser active layer 101 to lower clad layer 100 or first upper clad layer 103 can be suppressed. Therefore, laser beams outputted from laser active layer 101 can more efficiently be outputted to optical modulation active layer 111.

The lower clad layer index of refraction of lower clad layer 100 and the first index of refraction of first upper clad layer 103 are both configured to be lower than an optical modulation index of refraction which is the index of refraction of optical modulator active layer 111. According to such a configuration, diffusion of modulated laser beams outputted as being modulated by optical modulator active layer 111 to lower clad layer 100 or first upper clad layer 103 can be suppressed. Therefore, modulated laser beams outputted from optical modulator active layer 111 can more efficiently be outputted to optical amplifier active layer 121.

In consideration of absorption of light by a semiconductor, semiconductor optical integrated element 1 according to the present first embodiment is configured such that the laser active layer index of refraction is higher than the optical modulation active layer index of refraction. With such a configuration, balance between optical output and ON/OFF characteristics (extinction ratio) of light in an optical modulator can satisfactorily be maintained.

An example in which semiconductor optical integrated element 1 according to the present first embodiment is configured such that, in consideration of absorption of light by the semiconductor, the laser active layer index of refraction is higher than the optical modulation active layer index of refraction is described. Contents of the present disclosure, however, are not limited to the one example. The laser active layer index of refraction and the optical modulation active layer index of refraction may be configured to substantially be equal to each other. When the laser active layer index of refraction and the optical modulation active layer index of refraction are configured to substantially be equal to each other, light is absorbed by application of a relatively small bias to the optical modulator, and hence a drive voltage of the modulator can be low.

The lower clad layer index of refraction of lower clad layer 100 and the second index of refraction of second upper clad layer 123 are both configured to be lower than an optical amplification index of refraction which is the index of refraction of optical amplification active layer 121. According to such a configuration, diffusion of optically amplified laser beams outputted as a result of optical amplification by optical amplification active layer 121 to lower clad layer 100 or second upper clad layer 123 can be suppressed. Therefore, optically amplified laser beams outputted from optical amplification active layer 121 can more efficiently be outputted to the outside of semiconductor optical integrated element 1.

The first index of refraction of first upper clad layer 103 is configured to be lower than the second index of refraction of second upper clad layer 123. Therefore, optically amplified laser beams that propagate through optical amplifier active layer 121 propagate also into second upper clad layer 123 which is an upper layer more readily than into laser active layer 101 and optical modulator active layer 111. Therefore, semiconductor optical integrated element 1 can output to the outside of semiconductor optical integrated element 1, optically amplified laser beams a light intensity central position of which is shifted more toward a side opposite to lower clad layer 100 than laser beams that propagate through laser active layer 101 and modulated laser beams that propagate through optical modulator active layer 11, that is, optically amplified laser beams the light intensity central position of which is shifted more toward second upper clad layer 123 which is opposite to lower clad layer 100. Therefore, semiconductor optical integrated element 1 that can achieve further increase in output can be provided.

In optical amplifier active layer 121, with propagation of light, light is amplified by stimulated emission and a total quantity of light increases. Light has a property to propagate through a layer high in index of refraction, and second tipper clad layer 123 is higher in index of refraction than first upper clad layer 103. Therefore, a distribution of light that propagates through an optical amplifier spreads in the direction of second upper clad layer 123 as light propagates. Stimulated emission that occurs in optical amplifier active layer 121 is caused in accordance with a density of light in optical amplifier active layer 121 and an amount of injected carriers. When the density of light that propagates through an active layer is too high as compared with the amount of injected carriers, stimulated emission does not occur and amplification gain per unit length is saturated. According to the present embodiment, some of light propagates through second upper clad layer 123, and hence the density of light in optical amplifier active layer 121 can be kept low. Therefore, since stimulated emission keeps occurring and light is kept amplified, higher output of the semiconductor optical integrated element can be achieved. Therefore, semiconductor optical integrated element 1 that can achieve further increase in output can be provided.

Laser active electrode 105 is a plate-like electrode for providing a current between laser active electrode 105 and lower electrode 11. Laser active electrode 105 is arranged such that lower clad layer 100, laser active layer 101 layered on lower clad layer 100, and first upper clad layer 103 layered on laser active layer 101 are located between laser active electrode 105 and lower electrode 11. Therefore, semiconductor optical integrated element 1 that can achieve further increase in output can be provided.

Optical modulation electrode 115 is a plate-like electrode for providing a current between optical modulation electrode 115 and lower electrode 11. Optical modulation electrode 115 is arranged such that lower clad layer 100, optical modulation active layer 111 layered on lower clad layer 100, and first upper clad layer 103 layered on optical modulation active layer 111 are located between optical modulation electrode 115 and lower electrode 11.

Optical amplification electrode 125 is a plate-like electrode for providing a current between optical amplification electrode 125 and lower electrode 11. Optical amplification electrode 125 is arranged such that lower clad layer 100, optical amplification active layer 121 layered on lower clad layer 100, and second upper clad layer 123 layered on optical amplification active layer 121 are located between optical amplification electrode 125 and lower electrode 11. As shown in FIG. 1, optical amplification electrode 125 is arranged such that optical modulation electrode 115 is located between optical amplification electrode 125 and laser active electrode 105.

In semiconductor optical integrated element 1 according to the first embodiment, first upper clad layer 103 is composed, for example, of n-type InP having a thickness of 2.5 μm such that a mode of light is not applied to laser active electrode 105 and optical modulation electrode 115 having a large light absorption coefficient. Second upper clad layer 123, on the other hand, is composed, for example, of n-type InGaAsP or AlGaInAs having a thickness of 2.5 μm such that a mode of light is not applied to optical amplification electrode 125 having a large light absorption coefficient. Such combination achieves an effect to suppress light absorption by the electrodes and to be able to generate high optical output.

In another example of semiconductor optical integrated element 1, second upper clad layer 123 may have a multilayer structure together with a high-refraction-index semiconductor layer 151 containing a mixed crystal semiconductor of n-type InP and n-type InGaAsP or n-type AlGaInAs higher in index of refraction than n-type InP. For example, second upper clad layer 123 may have such a structure that n-type InP having a thickness of 0.4 μm, n-type InGaAsP having a thickness of 2.0 μm as the high-refraction-index semiconductor layer, and n-type InP having a thickness of 0.1 μm are layered sequentially from a side of the semiconductor substrate. Arrangement of an n-type InP layer having the thickness of 0.4 μm between optical amplifier active layer 121 and the high-refraction-index semiconductor layer can suppress occurrence of light loss due to sudden change in light mode in transition of light in a waveguide from a region where first upper clad layer 103 is formed to a region where second upper clad layer 123 is formed. With such a structure, second upper clad layer 123 is higher in index of refraction than first upper clad layer 103, and a center of a mode of light guided through an optical amplifier portion 40 is shifted above a center of a mode of light guided through a laser portion 20. Therefore, some of light propagates through second upper clad layer 123, the density of light in optical amplifier active layer 121 can be kept low, stimulated emission can keep occurring, and light can be kept amplified. Therefore, semiconductor optical integrated element 1 that can achieve further increase in output can be provided.

As described above, semiconductor optical integrated element 1 according to one aspect of the present invention generates and outputs laser beams, and includes laser active layer 101, optical modulation active layer 111, optical amplification active layer 121, first upper clad layer 103, and second upper clad layer 123. Laser active layer 101 generates laser beams. As shown in FIG. 1, optical modulation active layer 111 is juxtaposed to laser active layer 101 and outputs modulated laser beams obtained by optical modulation of laser beams generated by laser active layer 101. As shown in FIG. 1, optical amplification active layer 121 is juxtaposed to optical modulation active layer 111, and outputs amplified laser beams obtained by amplification of intensity of modulated laser beams outputted from optical modulation active layer 111. First upper clad layer 103 has the first index of refraction, and is arranged on the upper surface of laser active layer 101 and the upper surface of optical modulation active layer 111 as shown in FIG. 1. Second upper clad layer 123 has the second index of refraction different from the first index of refraction, and is juxtaposed to first upper clad layer 103 and arranged on the upper surface of optical amplification active layer 121 as shown in FIG. 1. Amplified laser beams outputted from optical amplification active layer 121 are outputted as being shifted above modulated laser beams outputted from optical modulation active layer 111. Therefore, some of light propagates through second upper clad layer 123, the density of light in optical amplifier active layer 121 can be kept low, stimulated emission can keep occurring, and light can be kept amplified. Therefore, semiconductor optical integrated element 1 that can achieve further increase in output can be provided.

As described above, in semiconductor optical integrated element 1 according to one aspect of the present invention, the first index of refraction is lower than the second index of refraction. Amplified laser beams outputted from optical amplification active layer 121 are outputted as being shifted in the direction of second upper clad layer 123 having the second index of refraction higher than the first index of refraction, as compared with modulated laser beams outputted from optical modulation active layer 111. Therefore, some of light propagates through second upper clad layer 123, the density of light in optical amplifier active layer 121 can be kept low, stimulated emission can keep occurring, and light can be kept amplified. Therefore, semiconductor optical integrated element 1 that can achieve further increase in output can be provided.

As described above, in semiconductor optical integrated element 1 according to one aspect of the present invention, laser active layer 101 has the laser active layer index of refraction higher than the first index of refraction. Optical modulation active layer 111 has the optical modulation active layer index of refraction higher than the first index of refraction. Optical amplification active layer 121 has the optical amplification active layer index of refraction higher than the second index of refraction. Therefore, semiconductor optical integrated element 1 performs a function for efficient propagation of light to laser active layer 101, optical amplifier active layer 121, and the inside of optical amplification active layer 121. Therefore, semiconductor optical integrated element 1 that can achieve further increase in output can be provided.

As described above, in semiconductor optical integrated element 1 according to one aspect of the present invention, the laser active layer index of refraction is equal to higher than the optical modulation active layer index of refraction. Therefore, semiconductor optical integrated element 1 that can achieve further increase in output can be provided.

Semiconductor optical integrated element 1 described above can be manufactured with a method as below. Lower electrode 11 is arranged. Semiconductor substrate 10 is arranged on the upper surface of arranged lower electrode 11. Laser active layer 101, optical modulation active layer 111, and optical amplification active layer 121 are arranged in parallel on the upper surface of arranged semiconductor substrate 10. Arranged first upper clad layer 103 is arranged on the upper surface of laser active layer 101 and optical modulation active layer 111. A material higher in index of refraction than arranged first upper clad layer 103 is selected. Second upper clad layer 123 containing the selected material is arranged on the upper surface of optical amplification active layer 121. Laser active electrode 105 and optical modulation electrode 115 are arranged in parallel on the upper surface of arranged first upper clad layer 103. Optical amplification electrode 125 is arranged on the tipper surface of second upper clad layer 123 containing the selected material higher in index of refraction than first upper clad layer 103. With such a structure, second upper clad layer 123 is higher in index of refraction than first upper clad layer 103, and the center of the mode of light guided through optical amplifier portion 40 is shifted above the center of the mode of light guided through laser portion 20. Therefore, some of light propagates through second upper clad layer 123, the density of light in optical amplifier active layer 121 can be kept low, stimulated emission can keep occurring, and light can be kept amplified. Therefore, semiconductor optical integrated element 1 that can achieve further increase in output can be provided.

The manufacturing method according to one aspect of the present invention manufactures semiconductor optical integrated element 1 to generate and output laser beams as shown in FIG. 1. As described above, the method of manufacturing semiconductor optical integrated element 1 includes the laser active layer arrangement step of arranging laser active layer 101 to generate laser beams, the optical modulation active layer arrangement step of arranging optical modulation active layer 121 as being juxtaposed to laser active layer 101, optical modulation active layer 121 outputting modulated laser beams obtained by optical modulation of laser beams generated by laser active layer 101 arranged in the laser active layer arrangement step, the optical amplification active layer arrangement step of arranging optical amplification active layer 125 as being juxtaposed to optical modulation active layer 121, optical amplification active layer 125 outputting amplified laser beams obtained by amplification of intensity of modulated laser beams outputted from optical modulation active layer 121 arranged in the optical modulation active layer arrangement step, the first upper clad layer arrangement step of arranging first upper clad layer 103 having the first index of refraction on the upper surface of laser active layer 101 arranged in the laser active layer arrangement step and the upper surface of optical modulation active layer 121 arranged in the optical modulation active layer arrangement step, the material selection step of selecting a material having the second index of refraction different from the first index of refraction, and the second upper clad layer arrangement step of arranging second upper clad layer 123 having the second index of refraction by containing the material selected in the material selection step on the upper surface of optical amplification active layer 125 arranged in the optical amplification active layer arrangement step. Therefore, in manufactured semiconductor optical integrated element 1, some of light propagates through second upper clad layer 123, the density of light in optical amplifier active layer 121 can be kept low, stimulated emission can keep occurring, and light can be kept amplified. Therefore, semiconductor optical integrated element 1 that can achieve further increase in output can be provided.

In the manufacturing method according to one aspect of the present invention, semiconductor optical integrated element 1 is manufactured such that the second index of refraction of the material selected in the material selection step is higher than the first index of refraction and amplified laser beams outputted from optical amplification active layer 125 are outputted as being shifted in the direction of second upper clad layer 123 having the second index of refraction higher than the first index of refraction, as compared with modulated laser beams outputted from optical modulation active layer 121. Therefore, in manufactured semiconductor optical integrated element 1, some of light propagates through second upper clad layer 123, the density of light in optical amplifier active layer 121 can be kept low, stimulated emission can keep occurring, and light can be kept amplified. Therefore, semiconductor optical integrated element 1 that can achieve further increase in output can be provided.

In the manufacturing method according to one aspect of the present invention, for laser active layer 101, a material having the laser active layer index of refraction higher than the first index of refraction is selected. For optical modulation active layer 121, a material having the optical modulation active layer index of refraction higher than the first index of refraction is selected. For optical amplification active layer 125, a material having the optical amplification active layer index of refraction higher than the second index of refraction is selected. Therefore, manufactured semiconductor optical integrated element 1 performs a function for efficient propagation of light to laser active layer 101, optical amplifier active layer 121, and the inside of optical amplification active layer 121. Therefore, semiconductor optical integrated element 1 that can achieve further increase in output can be provided.

In the manufacturing method according to one aspect of the present invention, for laser active layer 101 and optical modulation active layer 121, materials to allow the laser active layer index of refraction to be equal to or higher than the optical modulation active layer index of refraction are selected. Therefore, semiconductor optical integrated element 1 that can achieve further increase in output can be provided.

### REFERENCE SIGNS LIST

1. semiconductor optical integrated element; 10. semiconductor substrate; 100. lower clad layer; 101. laser active layer; 103. first upper clad layer; 105. laser active electrode; 111. optical modulation active layer; 115. optical modulation electrode; 121. optical amplification active layer; 123. second upper clad layer; 125. optical amplification electrode.

1. A semiconductor optical integrated element to generate and output laser beams, the semiconductor optical integrated element comprising:
a laser active layer to generate laser beams;
an optical modulation active layer juxtaposed to the laser active layer, the optical modulation active layer outputting modulated laser beams obtained by optical modulation of laser beams generated by the laser active layer;
an optical amplification active layer juxtaposed to the optical modulation active layer, the optical amplification active layer outputting amplified laser beams obtained by amplification of intensity of the modulated laser beams outputted from the optical modulation active layer;
a first upper clad layer having a first index of refraction, the first upper clad layer being arranged on an upper surface of the laser active layer and an upper surface of the optical modulation active layer; and
a second upper clad layer having a second index of refraction different from the first index of refraction, the second upper clad layer being juxtaposed to the first upper clad layer and arranged on an upper surface of the optical amplification active layer not on an upper surface of the laser active layer, wherein
the amplified laser beams outputted from the optical amplification active layer are outputted as being shifted above the modulated laser beams outputted from the optical modulation active layer.

2. The semiconductor optical integrated element according to claim 1, wherein
the first index of refraction is lower than the second index of refraction, and
the amplified laser beams outputted from the optical amplification active layer are outputted as being shifted in a direction of the second upper clad layer having the second index of refraction higher than the first index of refraction, as compared with the modulated laser beams outputted from the optical modulation active layer.

3. The semiconductor optical integrated element according to claim 1, wherein
the laser active layer has a laser active layer index of refraction higher than the first index of refraction,
the optical modulation active layer has an optical modulation active layer index of refraction higher than the first index of refraction, and
the optical amplification active layer has an optical amplification active layer index of refraction higher than the second index of refraction.

4. The semiconductor optical integrated element according to claim 3, wherein
the laser active layer index of refraction is equal to or higher than the optical modulation active layer index of refraction.

5. A manufacturing method of manufacturing a semiconductor optical integrated element to generate and output laser beams, the manufacturing method comprising:
a laser active layer arrangement step of arranging a laser active layer to generate laser beams;
an optical modulation active layer arrangement step of arranging an optical modulation active layer as being juxtaposed to the laser active layer, the optical modulation active layer outputting modulated laser beams obtained by optical modulation of laser beams generated by the laser active layer arranged in the laser active layer arrangement step;
an optical amplification active layer arrangement step of arranging an optical amplification active layer as being juxtaposed to the optical modulation active layer, the optical amplification active layer outputting amplified laser beams obtained by amplification of intensity of modulated laser beams outputted from the optical modulation active layer arranged in the optical modulation active layer arrangement step;
a first upper clad layer arrangement step of arranging a first upper clad layer having a first index of refraction on an upper surface of the laser active layer arranged in the laser active layer arrangement step and an upper surface of the optical modulation active layer arranged in the optical modulation active layer arrangement step;
a material selection step of selecting a material having a second index of refraction different from the first index of refraction; and
a second upper clad layer arrangement step of arranging a second upper clad layer having the second index of refraction by containing the material selected in the material selection step on an upper surface of the optical amplification active layer arranged in the optical amplification active layer arrangement step, not on an upper surface of the laser active layer.

6. The manufacturing method according to claim 5, wherein
the second index of refraction of the material selected in the material selection step is higher than the first index of refraction, and
the semiconductor optical integrated element is manufactured such that the amplified laser beams outputted from the optical amplification active layer are outputted as being shifted in a direction of the second upper clad layer having the second index of refraction higher than the first index of refraction, as compared with the modulated laser beams outputted from the optical modulation active layer.

7. The manufacturing method according to claim 5, wherein
a material having a laser active layer index of refraction higher than the first index of refraction is selected for the laser active layer,
a material having an optical modulation active layer index of refraction higher than the first index of refraction is selected for the optical modulation active layer, and
a material having an optical amplification active layer index of refraction higher than the second index of refraction is selected for the optical amplification active layer.

8. The manufacturing method according to claim 7, wherein
materials to allow the laser active layer index of refraction to be equal to or higher than the optical modulation active layer index of refraction are selected for the laser active layer and the optical modulation active layer.
